(19) United States
(12) Patent Application Publication
(10) Pub. No.: US 2021/0070952 A1
(43) Pub. Date: Mar. 11, 2021

(54) HEAT-CONDUCTIVE SHEET AND METHOD FOR MANUFACTURING SAME

(71) Applicant: Fuji Polymer Industries Co., Ltd., Nagoya-shi, Aichi (JP)

(72) Inventor: Katsuyuki SUZUMURA, Aichi (JP)

(21) Appl. No.: 17/044,625

(22) PCT Filed: Oct. 10, 2019
(86) PCT No.: PCT/JP2019/040008

§ 371 Date: Oct. 1, 2020

(30) Foreign Application Priority Data
Nov. 16, 2018 (JP) 2018-215634

(51) Int. Cl. C08J 5/18; C08L 83/04; H01L 23/373; C08K 3/22; C08K 3/38; C08K 7/18

(52) U.S. Cl. CPC C08J 5/18; C08L 83/04; H01L 23/373; C08K 3/22; C08K 2201/013; C08K 7/18; C08K 2003/2227; C08K 2003/385; C08K 2201/001; C08K 3/38

(57) ABSTRACT

A thermally conductive sheet 10 contains a matrix resin 11, filler molded pieces 12 containing a first thermally conductive filler 15 with shape anisotropy, and a second thermally conductive filler 13. The filler molded pieces 12 contain a binder resin 14 and the first thermally conductive filler 15. The first thermally conductive filler 15 is oriented in the thickness direction of each of the filler molded pieces 12. The first thermally conductive filler 15 is also oriented in the thickness direction of the thermally conductive sheet 10 when present in the thermally conductive sheet 10. This configuration provides a thermally conductive sheet with a high thermal conductivity and a large size, and a method for producing the thermally conductive sheet.

### TECHNICAL FIELD

The present invention relates to a thermally conductive sheet used for thermally conductive components such as electronic components and a method for producing the thermally conductive sheet. More specifically, the present invention relates to a thermally conductive sheet containing a molded filler and a method for producing the thermally conductive sheet.

### BACKGROUND ART

Semiconductors used in computers (CPUs), transistors, light-emitting diodes (LEDs), etc. generate heat during operation, and the performance of electronic components including them may be damaged by the heat. For this reason, a heat dissipating member is attached to a heat generating member such as a CPU in these electronic components. The heat dissipating member is often made of metal. Therefore, the adhesion of the heat dissipating member to the heat generating member is enhanced by inserting a sheet-like or gel-like thermally conductive sheet between the heat generating member and the heat dissipating member, so that the heat transfer between them can be improved. Patent Document 1 proposes preparing a mixture of an epoxy resin and hexagonal boron nitride particles containing coarse particles and fine particles, and roll-pressing the mixture to form a sheet in which the particles are oriented in a particular direction. Patent Document 2 proposes a method for producing a sheet (i.e., a laminating and slicing method). The method includes the following steps of mixing a poly(meth)acrylic acid ester resin with plate-like boron nitride particles; using the mixture to form a sheet so that the plate-like boron nitride particles are oriented in a direction parallel to the surface of the sheet; laminating a plurality of the sheets; and slicing the laminated body in the thickness direction, thereby providing a sheet in which the plate-like boron nitride particles are arranged in the thickness direction of the slice. Patent Document 3 proposes orienting the filler by centrifugal molding and pressing.

### PRIOR ART DOCUMENTS

### Patent Documents

Patent Document 1: JP 2011-090868 A
Patent Document 2: JP 5454300 B2
Patent Document 3: JP 2017-037833 A

### DISCLOSURE OF INVENTION

### Problem to be Solved by the Invention

However, there is a need to further improve the thermal conductivity of a thermally conductive sheet.

The present invention provides a thermally conductive sheet with a high thermal conductivity and a method for producing the thermally conductive sheet.

### Means for Solving Problem

A thermally conductive sheet of the present invention contains a matrix resin, filler molded pieces containing a first thermally conductive filler with shape anisotropy, and a second thermally conductive filler. The filler molded pieces contain a binder resin and the first thermally conductive filler. The first thermally conductive filler is oriented in a thickness direction of each of the filler molded pieces. The first thermally conductive filler is also oriented in a thickness direction of the thermally conductive sheet when present in the thermally conductive sheet.

A method for producing a thermally conductive sheet of the present invention provides the thermally conductive sheet of the present invention. The method includes the following: a first step of forming a sheet or block by pressure processing of a mixture of a binder resin and a first thermally conductive filler with shape anisotropy so that the first thermally conductive filler is oriented in a main surface direction of the sheet or block; a second step of curing the binder resin and then cutting the sheet or block in a thickness direction to obtain filler molded pieces, in each of which the first thermally conductive filler is oriented in a thickness direction of the filler molded piece; and a third step of mixing the filler molded pieces, a matrix resin, and a second thermally conductive filler, molding the mixture into a sheet shape, and then curing the matrix resin.

### Effects of the Invention

The thermally conductive sheet of the present invention contains the matrix resin, the filler molded pieces containing the first thermally conductive filler with shape anisotropy, and the second thermally conductive filler. The filler molded pieces contain the binder resin and the first thermally conductive filler. The first thermally conductive filler is oriented in the thickness direction of each of the filler molded pieces. The first thermally conductive filler is also oriented in the thickness direction of the thermally conductive sheet when present in the thermally conductive sheet. Thus, the thermally conductive sheet can have a high thermal conductivity in the thickness direction.

The method for producing the thermally conductive sheet of the present invention includes the following: mixing the filler molded pieces, in each of which the first thermally conductive filler is oriented in the thickness direction, the matrix resin, and the second thermally conductive filler; molding the mixture into a sheet shape; and curing the matrix resin. Thus, a large-size thermally conductive sheet can be produced even without the use of, e.g., a magnetic field orientation method or a laminating and slicing method. Therefore, the production method of the present invention can efficiently and reasonably produce the thermally conductive sheet with high thermal conductive properties.

### BRIEF DESCRIPTION OF DRAWINGS

FIG. 1 is a schematically cross-sectional view of a thermally conductive sheet of an embodiment of the present invention.

FIG. 2A is a photograph (100×) of a side view of a filler molded piece in Example 1 and FIG. 2B is a photograph (100×) of a plan view of the filler molded piece.

FIGS. 3A to 3C are schematic diagrams illustrating an example of a method for producing a filler molded piece of the present invention.

### DESCRIPTION OF THE INVENTION

The present invention is directed to a thermally conductive sheet that contains a matrix resin, filler molded pieces containing a first thermally conductive filler with shape anisotropy, and a second thermally conductive filler. The filler molded pieces contain a binder resin and the first thermally conductive filler. The first thermally conductive filler is oriented in the thickness direction of each of the filler molded pieces. The first thermally conductive filler is also oriented in the thickness direction of the thermally conductive sheet when present in the thermally conductive sheet. Thus, the thermally conductive sheet can have high thermal conductive properties. The thermally conductive filler is also referred to as thermally conductive particles.

The first thermally conductive filler with shape anisotropy is preferably a filler having at least one shape selected from a plate and a needle. The plate shape is also referred to as a flat shape, a flaky shape, etc. The needle shape is also referred to as a rod shape, a fibrous shape, etc. The fillers having these shapes are likely to be oriented in a predetermined direction. Specifically, in the process of preparing a filler molded piece, when the shape-anisotropic filler is present in the sheet or block, the main surface of the plate-like filler tends to be oriented in the plane direction of the main surface of the sheet or block, e.g., it tends to be arranged substantially in parallel to the main surface of the sheet or block. Moreover, the longitudinal direction of the needle-like filler tends to be oriented in the plane direction of the main surface of the sheet or block, e.g., it tends to be arranged substantially in parallel to the main surface of the sheet or block. Then, the sheet or block is cut in the thickness direction (which is the direction corresponding to the shortest side of the sheet or block), e.g., along the straight line perpendicular to the longitudinal direction of the main surface of the sheet or block. As a result, filler molded pieces are obtained. Thus, in the plane of a filler molded piece that is orthogonal to the cutting surface and that is also orthogonal to the main surface of the sheet or block (i.e., that is different from the main surface of the sheet or block), the plate-like filler is likely to be oriented in the thickness direction of the filler molded piece (which is the direction corresponding to the shortest side of the filler molded piece), e.g., the longitudinal direction of the plate-like filler is likely to be substantially the same as the thickness direction of the filler molded piece. Moreover, the needle-like filler is likely to be oriented in the thickness direction of the filler molded piece, e.g., the longitudinal direction of the needle-like filler is likely to be substantially the same as the thickness direction of the filler molded piece. The first thermally conductive filler with shape anisotropy is preferably composed of at least one selected from boron nitride and alumina. The filler including these components has high thermal conductive properties as well as high electrical insulation properties.

The matrix resin and the binder resin are preferably the same type or different types of thermosetting resins. This is because the thermosetting resin has high heat resistance and high dimensional stability. Examples of the thermosetting resin include silicone polymer, epoxy resin, acrylic resin, urethane resin, polyimide resin, polyester resin, and phenol resin. Among them, the silicone polymer is suitable for both the matrix resin and the binder resin.

It is preferable that the filler molded pieces further contain at least one selected from a spherical thermally conductive filler and an irregularly-shaped thermally conductive filler. These fillers can fill the gaps between particles of the shape-anisotropic first thermally conductive filler in the individual filler molded pieces, so that the thermal conductive properties can be further improved.

The second thermally conductive filler is preferably at least one selected from a spherical thermally conductive filler and an irregularly-shaped thermally conductive filler. Thus, the second thermally conductive filler can fill the gaps between the filler molded pieces in the thermally conductive sheet, thereby increasing the thermal conductive properties of the thermally conductive sheet.

The higher the thermal conductivity of the thermally conductive sheet, the better. For example, the thermal conductivity is preferably 1.5 W/m·K or more, more preferably 2.0 W/m·K or more, and further preferably 11 W/m·K or more.

The method for producing the thermally conductive sheet of the present invention includes the following steps:

(1)ₐ first step of forming a sheet or block by pressure processing of a mixture (I) of the binder resin and the first thermally conductive filler with shape anisotropy so that the first thermally conductive filler is oriented in the main surface direction of the sheet or block;

(2) a second step of curing the binder resin and then cutting the sheet or block in the thickness direction to obtain filler molded pieces, in each of which the first thermally conductive filler is oriented in the thickness direction of the filler molded piece; and

(3) a third step of mixing the filler molded pieces, the matrix resin, and the second thermally conductive filler, molding the resulting mixture (II) into a sheet shape, and then curing the matrix resin.

In the production method of the thermally conductive sheet of the present invention, due to the presence of the filler molded pieces, a large-size thermally conductive sheet can be produced even without the use of, e.g., a magnetic field orientation method or a laminating and slicing method. Therefore, the production method of the present invention can efficiently and reasonably produce the thermally conductive sheet with high thermal conductive properties. In this case, the large size (large area) means 100 mm or more in length and 100 mm or more in width, and preferably 300 mm or more in length and 400 mm or more in width. The thickness of the thermally conductive sheet may be the same as that of a conventionally known thermally conductive sheet and is preferably, e.g., 0.3 mm or more and 5.0 mm or less.

The pressure processing of the mixture (I) in the first step may be at least one selected from pressing and rolling.

The molding of the mixture (II) into a sheet-like material in the third step is preferably performed by at least one selected from pressing and rolling in terms of forming a large size (wide area) sheet. Moreover, continuous molding can be performed particularly by pressure rolls.

The binder resin and the matrix resin may be cured either by using an organic peroxide as a curing agent or by an addition reaction using a platinum group metal catalyst. An appropriate method can be selected that allows these resins to be thermally cured in the end and provides electrically stable thermal conductive properties or volume specific resistance.

When a silicone polymer is selected as a binder resin for the filler molded pieces, it is preferable that the mixture (I) contains the following components a to c (where the component c is one of components c1 and c2) in the first step.

(Component a) 100 parts by weight of polyorganosiloxane

(Component b) 50 to 2500 parts by weight of first thermally conductive filler with respect to 100 parts by weight of component a

(Component c)
(Component c1) platinum group metal catalyst
(Component c2) 0.01 to 5 parts by weight of organic peroxide with respect to 100 parts by weight of component a

When a silicone polymer is selected as a binder resin for the filler molded pieces, it is more preferable that the mixture (I) contains the following components a to d (where the component c is one of components c1 and c2) in the first step in terms of improving the thermal conductive properties.

(Component a) 100 parts by weight of polyorganosiloxane

(Component b) 50 to 2500 parts by weight of first thermally conductive filler with respect to 100 parts by weight of component a

(Component c)
(Component c1) platinum group metal catalyst
(Component c2) 0.01 to 5 parts by weight of organic peroxide with respect to 100 parts by weight of component a

(Component d) 10 to 500 parts by weight of at least one selected from a spherical thermally conductive filler and an irregularly-shaped thermally conductive filler with respect to 100 parts by weight of component a

When a silicone polymer is selected as a matrix resin for the thermally conductive sheet, it is preferable that the mixture (II) contains the following components A to D (where the component D is one of components D1 and D2) in the third step.

(Component A) 100 parts by weight of polyorganosiloxane

(Component B) 100 to 2500 parts by weight of filler molded pieces with respect to 100 parts by weight of component A

(Component C) 100 to 2500 parts by weight of second thermally conductive filler with respect to 100 parts by weight of component A

(Component D)
(Component D1) platinum group metal catalyst
(Component D2) 0.01 to 5 parts by weight of organic peroxide with respect to 100 parts by weight of component A

The silicone polymer may be either an addition curable silicone polymer or an organic peroxide curable silicone polymer.

When the silicone polymer is an addition curable silicone polymer, the polyorganosiloxane constituting the binder resin and the matrix resin contains a base polymer component and a crosslinking agent component, which will be described later, and is usually stored separately in a solution A and a solution B. For example, both the solution A and the solution B contain the base polymer component. The solution A further contains a curing catalyst such as a platinum group metal catalyst. The solution B further contains the crosslinking agent component. The polyorganosiloxane is commercially available in this condition.

When the silicone polymer is an organic peroxide curable silicone polymer, the polyorganosiloxane constituting the binder resin and the matrix resin preferably has at least two silicon atom-bonded alkenyl groups per molecule. Examples of the alkenyl group include vinyl group, allyl group, and propenyl group. The organic groups other than the alkenyl group of the polyorganosiloxane include the following: alkyl groups such as methyl, ethyl, propyl, butyl, pentyl, hexyl, octyl, decyl, and dodecyl groups; aryl groups such as phenyl and tolyl groups; aralkyl groups such as β-phenylethyl group; and halogen-substituted alkyl groups such as 3,3,3-trifluoropropyl and 3-chloropropyl groups.

The polyorganosiloxane may have a small amount of hydroxyl groups, e.g., at the end of the molecular chain. The molecular structure of the polyorganosiloxane may be a linear, a branched linear, a ring, or a network structure. Two or more types of polyorganosiloxane may be used in combination.

The molecular weight of the polyorganosiloxane is not particularly limited, and the polyorganosiloxane may be in any form, including, e.g., a low-viscosity liquid and a high-viscosity raw rubber. It is preferable that the polyorganosiloxane has a viscosity of 100 mPa·s or more at 25° C. in order to form a rubber-like elastic body by curing. It is more preferable that the polyorganosiloxane is in the form of raw rubber having a polystyrene-equivalent number average molecular weight of 200,000 to 700,000 measured by gel permeation chromatography (GPC).

[Binder Resin, Matrix Resin]

Next, each component of the binder resin and the matrix resin will be described.

(1) Base Polymer Component

The base polymer component is preferably a polyorganosiloxane having two or more alkenyl groups bonded to silicon atoms per molecule. In the polyorganosiloxane, two alkenyl groups having preferably 2 to 8 carbon atoms, and more preferably 2 to 6 carbon atoms such as vinyl groups or allyl groups, are bonded to the silicon atoms per molecule. The viscosity of the polyorganosiloxane is preferably 10 to 1000000 mPa·s, and more preferably 100 to 100000 mPa·s at 25° C. in terms of workability and curability.

Specifically, a polyorganosiloxane expressed by the following general formula (chemical formula 1) is used. The polyorganosiloxane has an average of two or more alkenyl groups per molecule, in which the alkenyl groups are bonded to silicon atoms at the ends of the molecular chain. The polyorganosiloxane expressed by the general formula (1) is a linear polyorganosiloxane having both ends blocked with triorganosiloxy groups. The linear polyorganosiloxane may include a small amount of branched structure (trifunctional siloxane units) in the molecular chain.

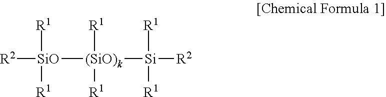

In the general formula (chemical formula 1), R¹ represents substituted or unsubstituted monovalent hydrocarbon groups that are the same as or different from each other and have no aliphatic unsaturated bond, R² represents alkenyl groups that are the same as or different from each other, and k represents 0 or a positive integer. The monovalent hydrocarbon groups represented by R¹ have, e.g., 1 to 10 carbon atoms, and more preferably 1 to 6 carbon atoms. Specific examples of the monovalent hydrocarbon groups include the following: alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups. The alkenyl groups represented by R² have, e.g., 2 to 6 carbon atoms, and more preferably 2 to 3 carbon atoms. Specific examples of the alkenyl groups include vinyl, allyl, propenyl, isopropenyl, butenyl, isobutenyl, hexenyl, and cyclohexenyl groups. In particular, the vinyl group is preferred. In the general formula (chemical formula 1), k is typically 0 or a positive integer satisfying 0≤k≤10000, preferably 5≤k≤2000, and more preferably 10≤k≤1200.

The component a and the component A may also include a polyorganosiloxane having three or more, typically 3 to 30, and preferably about 3 to 20, alkenyl groups bonded to silicon atoms per molecule. The alkenyl groups have 2 to 8 carbon atoms, and preferably 2 to 6 carbon atoms and can be, e.g., vinyl groups or allyl groups. The molecular structure may be a linear, ring, branched, or three-dimensional network structure. The polyorganosiloxane is preferably a linear polyorganosiloxane in which the main chain is composed of repeating diorganosiloxane units, and both ends of the molecular chain are blocked with triorganosiloxy groups. The viscosity of the linear polyorganosiloxane is preferably 10 to 1000000 mPa·s, and more preferably 100 to 100000 mPa·s at 25° C.

Each of the alkenyl groups may be bonded to any part of the molecule. For example, the alkenyl group may be bonded to either a silicon atom that is at the end of the molecular chain or a silicon atom that is not at the end (but in the middle) of the molecular chain. In particular, a linear polyorganosiloxane expressed by the following general formula (chemical formula 2) is preferred. The linear polyorganosiloxane has 1 to 3 alkenyl groups on each of the silicon atoms at both ends of the molecular chain. In this case, however, if the total number of the alkenyl groups bonded to the silicon atoms at both ends of the molecular chain is less than 3, at least one alkenyl group is bonded to the silicon atom that is not at the end (but in the middle) of the molecular chain (e.g., as a substituent in the diorganosiloxane unit). As described above, the viscosity of the linear polyorganosiloxane is preferably 10 to 1000000 mPa·s at 25° C. in terms of workability and curability. Moreover, the linear polyorganosiloxane may include a small amount of branched structure (trifunctional siloxane units) in the molecular chain.

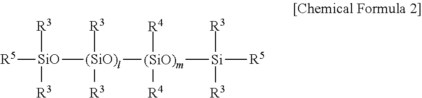

In the general formula (chemical formula 2), R³ represents substituted or unsubstituted monovalent hydrocarbon groups that are the same as or different from each other, and at least one of them is an alkenyl group, R⁴ represents substituted or unsubstituted monovalent hydrocarbon groups that are the same as or different from each other and have no aliphatic unsaturated bond, R⁵ represents alkenyl groups, and l and m represent 0 or a positive integer. The monovalent hydrocarbon groups represented by R³ preferably have 1 to 10 carbon atoms, and more preferably 1 to 6 carbon atoms. Specific examples of the monovalent hydrocarbon groups include the following; alkyl groups such as methyl, ethyl, propyl, isopropyl, butyl, isobutyl, tert-butyl, pentyl, neopentyl, hexyl, cyclohexyl, octyl, nonyl, and decyl groups; aryl groups such as phenyl, tolyl, xylyl, and naphthyl groups; aralkyl groups such as benzyl, phenylethyl, and phenylpropyl groups; alkenyl groups such as vinyl, allyl, propenyl, isopropenyl, butenyl, hexenyl, cyclohexenyl, and octenyl groups; and substituted forms of these groups in which some or all hydrogen atoms are substituted by halogen atoms (fluorine, bromine, chlorine, etc.) or cyano groups, including halogen-substituted alkyl groups such as chloromethyl, chloropropyl, bromoethyl, and trifluoropropyl groups and cyanoethyl groups.

The monovalent hydrocarbon groups represented by R⁴ also preferably have 1 to 10 carbon atoms, and more preferably 1 to 6 carbon atoms. The monovalent hydrocarbon groups may be the same as the specific examples of R′, but do not include an alkenyl group.

The alkenyl groups represented by R⁵ have, e.g., 2 to 6 carbon atoms, and more preferably 2 to 3 carbon atoms. Specific examples of the alkenyl groups are the same as those of R² in the general formula (1), and the vinyl group is preferred.

In the general formula (chemical formula 2), 1 and m are typically 0 or positive integers satisfying 0<l+m≤10000, preferably 5≤l+m≤2000, and more preferably 10≤l+m≤1200. Moreover, 1 and m are integers satisfying 0<l/(l+m)≤0.2, and preferably 0.0011≤l/(l+m)≤0.1.

(2) Crosslinking Agent Component

The crosslinking agent component of the component a and the component A is preferably an organohydrogenpolysiloxane. The addition reaction (hydrosilylation) between SiH groups in the crosslinking agent component and alkenyl groups in the base polymer component of the component A produces a cured product. Any organohydrogenpolysiloxane that has two or more hydrogen atoms (i.e., Sill groups) bonded to silicon atoms per molecule may be used. The molecular structure of the organohydrogenpolysiloxane may be a linear, ring, branched, or three-dimensional network structure. The number of silicon atoms in a molecule (i.e., the degree of polymerization) is preferably 2 to 1000, and more preferably about 2 to 300.

The locations of the silicon atoms to which the hydrogen atoms are bonded are not particularly limited. The silicon atoms may be either at the ends or not at the ends (but in the middle) of the molecular chain. The organic groups bonded to the silicon atoms other than the hydrogen atoms may be, e.g., substituted or unsubstituted monovalent hydrocarbon groups that have no aliphatic unsaturated bond, which are the same as those of R¹ in the general formula (1).

The organohydrogenpolysiloxane may have a structure expressed by the following general formula (chemical formula 3).

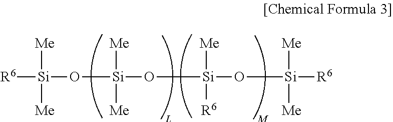

In the formula, R⁶ may be the same as or different from each other and represents hydrogen, alkyl groups, phenyl groups, epoxy groups, acryloyl groups, methacryloyl groups, or alkoxy groups, and at least two of them are hydrogen. L represents an integer of 0 to 1000, and preferably 0 to 300, and M represents an integer of 1 to 200.

(3) Catalyst Component

The component c1 of the binder resin and the component D1 of the matrix resin may be a platinum group metal catalyst used for a hydrosilylation reaction. Examples of the platinum group metal catalyst include platinum-based, palladium-based, and rhodium-based catalysts. The platinum-based catalysts include, e.g., platinum black, platinum chloride, chloroplatinic acid, a reaction product of chloroplatinic acid and monohydric alcohol, a complex of chloroplatinic acid and olefin or vinylsiloxane, and platinum bisacetoacetate.

The platinum group metal catalyst may be mixed in an amount necessary for the curing of polyorganosiloxane that is the component a or the component A, and preferably in an amount capable of sufficiently curing the polyorganosiloxane. The amount of the platinum group metal catalyst can be appropriately adjusted in accordance with the desired curing rate or the like. The platinum group metal catalyst is usually contained in the silicone polymer (e.g., a two-part room temperature curing silicone polymer) used in the production of the thermally conductive sheet of the present invention. Further, an additional platinum group metal catalyst may be mixed with the silicone polymer in the production of the thermally conductive sheet of the present invention in order to sufficiently cure the component a or the component A. The amount of the platinum group metal catalyst is preferably 0.01 to 1000 ppm, expressed in terms of the weight of metal atoms, with respect to the polyorganosiloxane component.

The “amount capable of sufficiently curing the polyorganosiloxane” means that the amount of the platinum group metal catalyst is large enough for the cured product to be able to have an Asker C hardness of 5 or more.

The component c2 of the binder resin and the component D2 of the matrix resin are organic peroxides and generate radicals when heated, causing crosslinking reactions of the component a and the component A, respectively. Examples of the organic peroxide include the following: acyl peroxides such as benzoyl peroxide and bis(p-methylbenzoyl) peroxide; alkyl peroxides such as di-tert-butyl peroxide, 2,5-dimethyl-2,5-di(tert-butylperoxy)hexane, tert-butyl cumyl peroxide, and dicumyl peroxide; and ester-based organic peroxides such as tert-butyl perbenzoate. The amount of the component c2 of the binder resin and the amount of the component D2 of the matrix resin are preferably 0.01 to 5 parts by weight, and more preferably 0.1 to 4 parts by weight with respect to 100 parts by weight of the component a and 100 parts by weight of the component A, respectively.

[Second Thermally Conductive Filler]

The second thermally conductive filler (component C) is preferably added in an amount of 100 to 2500 parts by weight with respect to 100 parts by weight of the component A. The addition of the second thermally conductive filler can maintain a high thermal conductivity of the thermally conductive sheet. The thermally conductive filler is preferably composed of at least one selected from alumina, zinc oxide, magnesium oxide, aluminum nitride, boron nitride, aluminum hydroxide, and silica. The thermally conductive filler may have various shapes such as spherical, flaky, and polyhedral. When alumina is used, α-alumina with a purity of 99.5% by weight or more is preferred. The specific surface area of the second thermally conductive filler is preferably 0.06 to 10 m²/g. The specific surface area is a BET specific surface area and is measured in accordance with JIS R 1626. The average particle size of the second thermally conductive filler is preferably 0.1 to 100 μm. The particle size is D50 (median diameter) in a particle size distribution measured by a laser diffraction scattering method. The method may use, e.g., a laser diffraction/scattering particle size distribution analyzer LA-950 S2 manufactured by HORIBA, Ltd.

The second thermally conductive filler preferably includes at least two types of inorganic particles with different average particle sizes. This is because small-size thermally conductive inorganic particles can fill the spaces between large-size inorganic particles, which can provide nearly the closest packing and improve the thermal conductive properties.

It is preferable that the inorganic particles are surface treated with a silane compound or its partial hydrolysate. The silane compound is expressed by R(CH₃)ₐSi(OR′)₃₋ₐ, where R represents a substituted or unsubstituted organic group having 1 to 20 carbon atoms, R′ represents an alkyl group having 1 to 4 carbon atoms, and a is 0 or 1. Examples of an alkoxysilane compound (simply referred to as “silane” in the following) expressed by R(CH₃)ₐSi(OR′)₃₋ₐ, where R represents a substituted or unsubstituted organic group having 1 to 20 carbon atoms, R′ represents an alkyl group having 1 to 4 carbon atoms, and a is 0 or 1, include the following: methyltrimethoxysilane; ethyltrimethoxysilane; propyltrimethoxysilane; butyltrimethoxysilane; pentyltrimethoxysilane; hexyltrimethoxysilane; hexyltriethoxysilane; octyltrimethoxysilane; octyltriethoxysilane; decyltrimethoxysilane; decyltriethoxysilane; dodecyltrimethoxysilane; dodecyltriethoxysilane; hexadecyltrimethoxysilane; hexadecyltriethoxysilane; octadecyltrimethoxysilane; and octadecyltriethoxysilane. These silane compounds may be used individually or in combinations of two or more. The alkoxysilane and one-end silanol siloxane may be used together as the surface treatment agent. In this case, the surface treatment may include adsorption in addition to a covalent bond. The amount of particles with an average particle size of 2 μm or more is preferably 50% by weight or more with respect to 100% by weight of the total amount of particles.

[Other Components]

The mixture (II) may include components other than the above as needed. For example, the mixture (II) may include an inorganic pigment such as colcothar, and alkyltrialkoxysilane used, e.g., for the surface treatment of the filler. The material used for the surface treatment of the filler may be, e.g., alkoxy group-containing silicone.

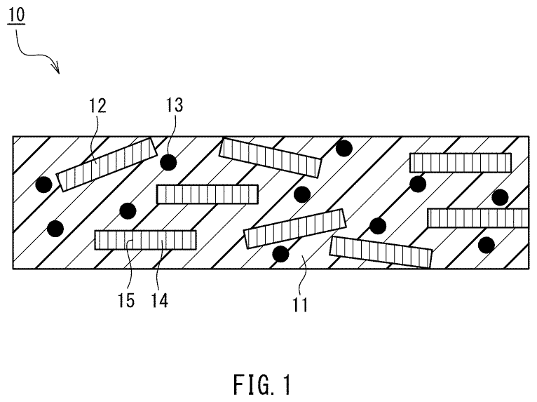

FIG. 1 is a schematically cross-sectional view of a thermally conductive sheet of an embodiment of the present invention. A thermally conductive sheet 10 contains a matrix resin 11, filler molded pieces 12 containing a first thermally conductive filler with shape anisotropy, and a second thermally conductive filler 13. The filler molded pieces 12 contain a binder resin 14 and the first thermally conductive filler 15. The first thermally conductive filler 15 is oriented in the thickness direction of each of the filler molded pieces 12. The first thermally conductive filler 15 is also oriented in the thickness direction of the thermally conductive sheet 10 when present in the thermally conducive sheet 10.

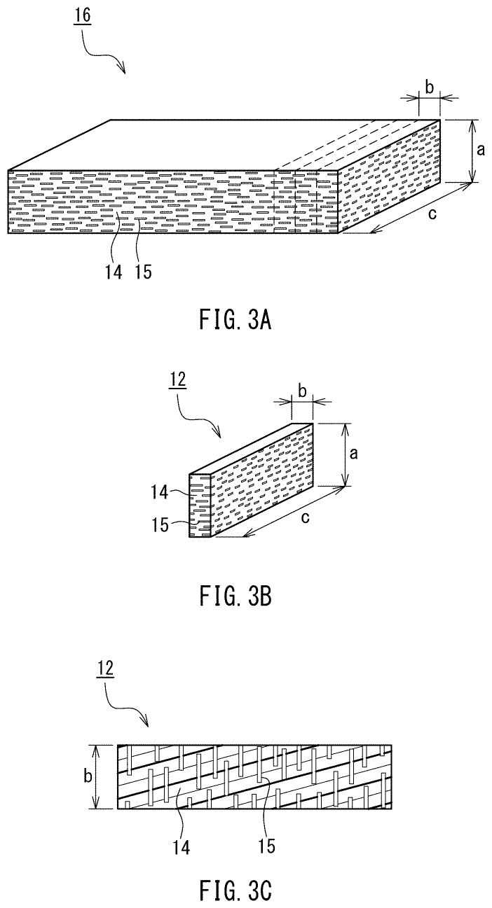

FIGS. 3A to 3C are schematic diagrams illustrating a method for producing the filler molded pieces 12 in an embodiment of the present invention. First, as shown in FIG. 3A, a sheet is formed by pressure processing of a mixture (I) of the binder resin 14 and the first thermally conductive filler 15 with shape anisotropy so that the first thermally conductive filler 15 is oriented in the main surface direction of the sheet (first step).

Then, the binder resin 14 in the sheet is cured, resulting in a sheet-like molded body 16 with a thickness a. Next, the sheet-like molded body 16 is cut in the thickness direction, e.g., along the dotted line in FIG. 3A to obtain the filler molded pieces 12. In this case, assuming that the sheet-like molded body 16 has a thickness a and a width c (where c>a, because the molded body 16 is in the form of a sheet), the relationship between the thickness a and a cutting width b is defined as a>b. Due to the relationship a>b, the first thermally conductive filler 15 is likely to be oriented in the thickness direction of the thermally conductive sheet when the filler molded pieces 12 are contained in the thermally conductive sheet. FIG. 3B is a perspective view of a filler molded piece 12 that is obtained by cutting the sheet-like molded body 16. FIG. 3C is a side view (i.e., ab view) of the filler molded piece 12. In this manner, the filler molded pieces 12 are provided.

The sheet-like molded body 16 may be broken when it is cut. In such a case, the width c of the filler molded piece does not have to be maintained. As shown in FIG. 3B, assuming that the filler molded piece in the form of a rectangular parallelepiped has a thickness b (corresponding to the “cutting width b” as will be described later), a side a corresponding to the thickness a of the sheet-like molded body 16, and a side d which is the remaining side, the sheet-like molded body 16 may be cut so that the width c becomes smaller as long as the filler molded piece thus obtained has a shape that satisfies d≥a>b or a≥d>b.

The pressure processing of the mixture of the binder resin and the first thermally conductive filler may provide either a sheet or a block in the first step. As in the case of the sheet, the block is cut to a cutting width b to obtain the filler molded pieces 12, and each of the filler molded pieces 12 has a shape that satisfies c≥a>b or a≥c>b. Due to the relationship c≥a>b or a≥c>b, the first thermally conductive filler 15 is likely to be oriented in the thickness direction of the thermally conductive sheet when the filler molded pieces 12 are contained in the thermally conductive sheet.

### EXAMPLES

Hereinafter, the present invention will be described by way of examples. However, the present invention is not limited to the following examples.

<Thermal Conductivity>

A thermal resistance value (m²·K/W) was measured by a thermal resistance measurement method in accordance with ASTM D5470. Then, an approximate line graph was created by plotting the measured thickness on the X axis and the thermal resistance value on the Y axis. The reciprocal of the slope of this approximate line was determined as a thermal conductivity.

### Example 1

<Filler Molded Piece>

1. Material Components

(1) Silicone Component

A two-part room temperature curing silicone polymer containing a polyorganosiloxane was used as a silicone component in an amount shown in Table 1. The solution A contained a base polymer component and a platinum group metal catalyst. The solution B contained a base polymer component and an organohydrogenpolysiloxane (crosslinking agent component).

(2) Thermally Conductive Filler

A plate-like boron nitride filler (first thermally conductive filler) with a major axis of 700 μm and a minor axis of 50 μm and a spherical alumina filler with an average particle size of 2 μm were used in amounts shown in Table 1, respectively. The alumina filler was surface treated with a silane coupling agent (triethoxysilane), thereby preventing a reduction in the curing acceleration that is the catalytic ability of the Pt catalyst. In the surface treatment, 1 part by mass of the silane coupling agent was added to 100 parts by mass of the alumina filler, and the mixture was stirred uniformly. Then, the stirred alumina filler was spread evenly over, e.g., a tray and dried at 100° C. for 2 hours.

2. Mixing and Molding

The silicone component and the thermally conductive filler were weighed in amounts shown in Table 1 and mixed to form a compound. Next, the compound was sandwiched between PET films, which had been subjected to a release treatment, and rolled with even-speed rolls to form a sheet having a thickness a of 3.0 mm (see FIG. 3A). The sheet was heated at 100° C. for 15 minutes so that the silicone polymer was cured. Consequently, a sheet-like molded body was obtained, in which the plate-like boron nitride filler (first thermally conductive filler) was oriented in the main surface direction of the sheet-like molded body, that is, the main surface of the plate-like boron nitride filler (first thermally conductive filler) was arranged substantially in parallel to the main surface of the sheet-like molded body.

TABLE 1

| | | Example 1 |
|---|---|---|
| Silicone component | Solution A (parts by mass) | 50 |
| | Solution B (parts by mass) | 0.15 |

| | |
|---|---|
| Plate-like boron nitride filler (first thermally conductive filler) | 50 |
| (parts by mass) | |
| Spherical alumina filler | 10 |
| average particle size: 2 μm (parts by mass) | |

3. Cutting of Sheet-Like Molded Body

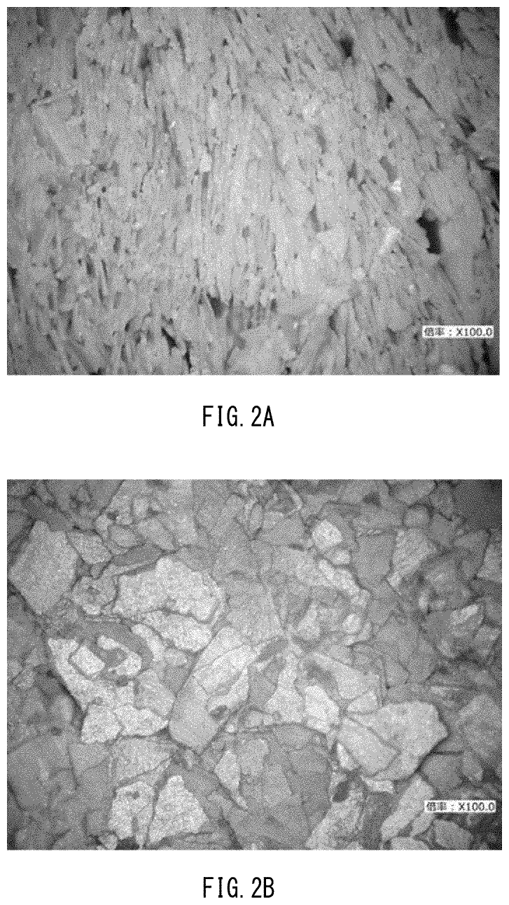

The sheet-like molded body was cut with a cutter in the thickness (a) direction at average intervals of 0.5 mm (see FIG. 3A). Thus, filler molded pieces were obtained. Each of the filler molded pieces was in the form of a rectangular parallelepiped having a length c of 5 mm, a width a of 3 mm, and a thickness b of 0.5 mm (see FIG. 3B). FIG. 2A shows a photograph (100×) of the side view (ab surface) of the filler molded piece. In FIG. 2A, the plate-like boron nitride filler (first thermally conductive filler) was oriented in the thickness b direction of the filler molded piece. FIG. 2B shows a photograph (100×) of the plan view (bc surface) of the filler molded piece. In FIG. 2B, the plane of the plate-like boron nitride filler (first thermally conductive filler) was observed.

<Production of Thermally Conductive Sheet>

The filler molded pieces, a silicone component (two-part room temperature curing silicone polymer) that was to be a matrix resin by curing, and a spherical alumina filler (second thermally conductive filler) were weighed in amounts shown in Table 2 and mixed. Then, the mixture was molded into a sheet shape, and the resulting sheet was cured by heating at 100° C. for 15 minutes. Consequently, a thermally conductive sheet was obtained, in which the plate-like boron nitride filler (first thermally conductive filler) was oriented in the thickness direction of the thermally conductive sheet. In other words, in a cutting surface that would be seen if the thermally conductive sheet was cut in the thickness direction, the longitudinal direction of the plate-like boron nitride filler (first thermally conductive filler) was oriented in the thickness direction of the thermally conductive sheet and was substantially the same as the thickness direction of the thermally conductive sheet.

The alumina filler was surface treated with a silane coupling agent (triethoxysilane). In the surface treatment, 1 part by mass of the silane coupling agent was added to 100 parts by mass of the alumina filler, and the mixture was stirred uniformly. Then, the stirred alumina filler was spread evenly over, e.g., a tray and dried at 100° C. for 2 hours.

FIG. 1 shows a schematic cross-sectional view of the thermally conductive sheet. Table 2 also shows the thermal conductivity and hardness of the thermally conductive sheet.

### Comparative Example 1

A thermally conductive sheet was produced in the following manner. Without using any filler molded piece, a silicone component that was to be a matrix resin by curing, a first thermally conductive filler, and a second thermally conductive filler were weighed in amounts shown in Table 2 and mixed. Then, the mixture was molded into a sheet shape, and the resulting sheet was cured by heating at 100° C. for 15 minutes. Table 2 also shows the thermal conductivity and hardness of the thermally conductive sheet of Comparative Example 1.

TABLE 2

| | | | Comparative |
|---|---|---|---|
| | | Example 1 | Example 1 |
| Silicone | Solution A | 25 | 50 |
| component | (parts by mass) | | |
| | Solution B | 25 | 50 |
| | (parts by mass) | | |

| | | |
|---|---|---|
| Filler molded piece (parts by mass) | 110 | — |
| Spherical alumina filler | 90 | 100 |
| (second thermally conductive filler) | | |
| average particle size: 2 μm (parts by mass) | | |
| Spherical alumina filler | 100 | 100 |
| (second thermally conductive filler) | | |
| average particle size: 35 μm (parts by mass) | | |
| Plate-like boron nitride filler | — | 50 |
| (first thermally conductive filler) | | |
| (parts by mass) | | |
| Thermal conductivity (W/m · K) | 2.08 | 1.07 |

Example 1 and Comparative Example 1 were the same in the weight ratio of the resin component and the thermally conductive filler. As is evident from Table 2, the thermally conductive sheet of Example 1 contained the filler molded pieces, in each of which the plate-like boron nitride filler was oriented in the thickness direction of the thermally conductive sheet, and thus had a higher thermal conductivity than the thermally conductive sheet of Comparative Example 1.

### INDUSTRIAL APPLICABILITY

The thermally conductive sheet of the present invention can be used to promote the dissipation of heat from various heat generating components to various heat dissipating materials, e.g., as a thermally conductive sheet that is interposed between the heat generating components such as electronic components and the heat dissipating materials such as metal.

### DESCRIPTION OF REFERENCE NUMERALS

1 Thermal conductivity measuring apparatus
2 Sensor
3a, 3b Sample
4 Tip of the sensor
5 Electrode for applied current
6 Electrode for resistance value (temperature measurement electrode)
10 Thermally conductive sheet
11 Matrix resin
12 Filler molded piece
13 Second thermally conductive filler
14 Binder resin
15 First thermally conductive filler
16 Molded body

1. A thermally conductive sheet comprising:
a matrix resin;
filler molded pieces containing a first thermally conductive filler with shape anisotropy; and
a second thermally conductive filler,
wherein the matrix resin, the filler molded pieces, and the second thermally conductive filler are mixed together,
the filler molded pieces contain a binder resin and the first thermally conductive filler,
the first thermally conductive filler is oriented in a thickness direction of each of the filler molded pieces, and
the first thermally conductive filler is also oriented in a thickness direction of the thermally conductive sheet when present in the thermally conductive sheet.

2. The thermally conductive sheet according to claim 1, wherein the first thermally conductive filler with shape anisotropy is a filler having at least one shape selected from a plate and a needle.

3. The thermally conductive sheet according to claim 1, wherein the first thermally conductive filler with shape anisotropy is composed of at least one selected from boron nitride and alumina.

4. The thermally conductive sheet according to claim 1, wherein the matrix resin and the binder resin are the same type or different types of thermosetting resins.

5. The thermally conductive sheet according to claim 1, wherein both the matrix resin and the binder resin are silicone polymers.

6. The thermally conductive sheet according to claim 1, wherein the filler molded pieces further contain at least one selected from a spherical thermally conductive filler and an irregularly-shaped thermally conductive filler.

7. The thermally conductive sheet according to claim 1, wherein the second thermally conductive filler contains at least one selected from a spherical thermally conductive filler and an irregularly-shaped thermally conductive filler.

8. The thermally conductive sheet according to claim 1, wherein a thermal conductivity of the thermally conductive sheet is 1.5 W/m·K or more.

9. A method for producing a thermally conductive sheet,
the thermally conducive sheet comprising:
a matrix resin;
filler molded pieces containing a first thermally conductive filler with shape anisotropy; and
a second thermally conductive filler,
wherein the matrix resin, the filler molded pieces, and the second thermally conductive filler are mixed together,
the filler molded pieces contain a binder resin and the first thermally conductive filler,
the first thermally conductive filler is oriented in a thickness direction of each of the filler molded pieces, and
the first thermally conductive filler is also oriented in a thickness direction of the thermally conductive sheet when present in the thermally conductive sheet,
the method comprising:
forming a sheet or block by pressure processing of a mixture of a binder resin and a first thermally conductive filler with shape anisotropy so that the first thermally conductive filler is oriented in a main surface direction of the sheet or block;
curing the binder resin and then cutting the sheet or block in a thickness direction to obtain filler molded pieces, in each of which the first thermally conductive filler is oriented in a thickness direction of the filler molded piece; and
mixing the filler molded pieces, a matrix resin, and a second thermally conductive filler, molding the mixture into a sheet shape, and then curing the matrix resin.

10. The method according to claim 9, wherein the pressure processing is at least one selected from pressing and rolling.

11. The thermally conductive sheet according to claim 1, wherein the second thermally conductive filler includes at least two types of inorganic particles with different average particle sizes.

12. The method according to claim 9, wherein the first thermally conductive filler with shape anisotropy is a filler having at least one shape selected from a plate and a needle.

13. The method according to claim 9, wherein the first thermally conductive filler with shape anisotropy is composed of at least one selected from boron nitride and alumina.

14. The method according to claim 9, wherein the matrix resin and the binder resin are the same type or different types of thermosetting resins.

15. The method according to claim 9, wherein both the matrix resin and the binder resin are silicone polymers.

16. The method according to claim 9, wherein the filler molded pieces further contain at least one selected from a spherical thermally conductive filler and an irregularly-shaped thermally conductive filler.

17. The method according to claim 9, wherein the second thermally conductive filler contains at least one selected from a spherical thermally conductive filler and an irregularly-shaped thermally conductive filler.

18. The method according to claim 9, wherein a thermal conductivity of the thermally conductive sheet is 1.5 W/m·K or more.
